(19) United States
(12) Patent Application Publication
(10) Pub. No.: US 2009/0200158 A1
(43) Pub. Date: Aug. 13, 2009

(54) HIGH POWER IMPULSE MAGNETRON SPUTTERING VAPOUR DEPOSITION

(75) Inventor: Arutiun P. Ehiasarian, Sheffield (GB)

Correspondence Address: TREXLER, BUSHNELL, GIANGIORGI,;BLACKSTONE & MARR, LTD., 105 WEST ADAMS STREET, SUITE 3600, CHICAGO, IL, 60603, US

(73) Assignee: SHEFFIELD HALLAM UNIVERSITY, Sheffield (GB)

(21) Appl. No.: 12/298,871

(22) PCT Filed: Apr. 24, 2007
(86) PCT No.: PCT/GB2007/001483

§ 371 Date: Nov. 3, 2008

(30) Foreign Application Priority Data
May 2, 2006 (GB) 0608582.3
Dec. 22, 2006 (GB) 0625730.7

(51) Int. Cl. C23C 14/35; H01J 37/34

(52) U.S. Cl. 204/192.12; 204/298.16

(57) ABSTRACT

Method and apparatus for physical vapour deposition (PVD) and in particular high power impulse magnetron sputtering (HIPIMS) deposition is described. The present apparatus and process provide for the creation of a weaker magnetic field in the region of the cathode which reduces the confinement of a significant part of the plasma near the target surface. By weakening the magnetic field in the region of the target, the deposition rate of materials at a substrate has been found to increase by a factor of 9 relative to that of conventional HIPIMS processes employing typical magnetic field strengths.

### FIELD OF THE INVENTION

The present invention relates to high power impulse magnetron sputtering (HIPIMS) physical vapour deposition (PVD) processes and apparatus and in particular a process and apparatus that provides an enhanced metal or compound deposition rate.

### BACKGROUND TO THE INVENTION

Physical Vapour Deposition (PVD) processes have been widely used for depositing thin films on substrates. Magnetron sputtering refers to the technique in which an external magnetic field is applied directly to a sputtering source to confine plasma electrons and increase the sputtering rate. One early magnetron sputtering technique employed was direct current magnetron sputtering (dcMS). However limitations of this process included low target utilisation and low ion flux in the vicinity of the substrate. This technique has been found to produce films having a porous microstructure due to low metal ionisation of the deposition flux from the target (cathode). Another well established technology is cathodic vacuum arc evaporation which produces highly ionized deposition flux but also material droplets that form large scale defects within the deposited coating.

Increasing the power supplied to the magnetron sputtering source so as to increase the plasma density at the sputtering target in turn increases the degree of target metal ionisation. The maximum average target power density is however limited by a number or factors including target overheating, plasma instability and arcing.

High power impulse magnetron sputtering (HIPIMS) is a more recently developed PVD technique which creates a high plasma density and ionised metal particles at low pressures without microparticle generation (Kouznetsov et al, Surface and Coating Technology 122 (2-3) (1999) 290). Coatings generated by the HIPIMS technique exhibit high substrate adhesion and enhanced wear resistance due to the elimination or reduction in coating imperfections during the deposition process (Ehiasarian et al, Surface and Coating Technology 163-164 (2003) 267-272) Pretreatment by the HIPIMS technique involving high-energy ion bombardment of the substrate in a HIPIMS environment provides clean interfaces and improved adhesion and overall performance of the coating (Ehiasarian et al. Thin Solid Films, Vol. 457, 2, 270-277).

Ionisation in conventional magnetron sputtering is generally very weak but is sought after as a means to produce high quality films and to carry out substrate pretreatments. The sputtering process itself generates mainly neutral atoms while ions ejected from the target comprise only <1% of the flux. However, additional ionisation can occur by a number of ways. As the neutral atoms progress through the plasma discharge, they may be ionised by collisions with highly energetic plasma electrons. Since the probability for collision and ionisation is proportional to the plasma density, it is generally desired to obtain the highest plasma density by additional sources or by increasing the power dissipated in the discharge. The HIPIMS method utilises the second approach and can achieve high current densities of the order of 4-5 A.cm⁻². This translates directly to high plasma densities of the order of 10¹³ cm⁻³ where the sputtered metal neutrals ejected from the target have a high probability of ionisation.

The high currents in magnetron sputtering and HIPIMS in particular are achieved by the presence of a specifically shaped magnetic field, which acts to trap and confine a significant part of the plasma near the target surface. The magnetic field is configured such that electrons are trapped in the vicinity of the target and follow a helical motion, which increases their path length in the given volume and increases the probability of ionising the working gas and sputtered metal neutrals. The strength of the magnetic field determines the degree of confinement and therefore stronger magnetic fields decrease the impedance of the discharge and allow higher discharge currents to be produced for the same target voltage.

However, whilst it is possible to generate coatings of superior quality using HIPIMS rather than convention dcMS, in general deposition rates are significantly lower.

A number of workers have investigated HIPIMS deposition rates. Christie et al. J. Vac. Sci. Technol., A 23 (2), 330, 2005 disclose a model which attempts to explain the decrease in deposition rate of HIPIMS relative to dcMS. According to the model predictions, the rate loss arises due to the high ionisation of the sputtered material near the target surface. Once ionised, a large fraction of these ions are accelerated back towards the sputtering target by the electric field of the cathode and become unavailable for deposition, instead contributing to the sputtering current.

Konstantinidis et al Journal of Applied Physics 99, 013307 (2006), investigated the influence of pulse duration on the plasma characteristics in HIPIMS discharges. The plasma was studied by time-resolved optical emission and absorption spectroscopies and the deposition rate monitored by a quartz microbalance. For a constant discharge power, the deposition rate was found to increase as the pulse length decreases. With a 5 μs pulse, for an average power of 300 W, the deposition rate was ˜70% of the deposition rate obtained in direct current magnetron sputtering at the same power. This difference in the deposition rate was found to be related to the sputtering regime. The authors comment that for long pulses, self sputtering seems to occur as demonstrated by time-resolved optical emission diagnostic of the discharge. However, the metallic vapour ionisation rate was found to diminish as the pulses shortened.

Konstantinidis et al Applied Physics Letter 88, 021501 (2006) also investigated the influence on the mobility and transport of metal ions in HIPIMS discharges by inductively coupled plasma. The author's experiments involved time-resolved optical emission and absorption spectrometry and current measurement at the substrate. Using this hybrid technique, ions were identified as reaching the substrate in two successive waves. Metal ions, only present in the second wave, were found to accelerate proportionally to the power supplied to the inductively coupled plasma. All the measurements conducted were made at 10 and 30 mTorr, with 10 μs long pulses at the magnetron cathode.

Bohlmark et al Plasma Sources Sci. Technol. 13 (2004) 654-661 present a study of how a magnetic field of a circular planar magnetron is affected when exposed to a pulsed high current discharge. The authors found that the magnetic field is severely deformed by the discharge. The deformation was found to mainly strengthen the magnetic field in the measurement area (between 2 and 7 cm from the target surface). The deformation was also found to go through two stages, the dominating part which occurs at an early stage of the pulse and is in phase with the axial discharge current. The second part, occurring later in the pulse, is not in phase with the discharge current and is seen as a wave travelling from the target.

Whilst a number of workers have investigated deposition rates, the deposition rate difference between dcMS and HIPIMS, with considerable ionisation degree, remains unsatisfactorily large. What is required therefore is a HIPIMS process capable of producing dense coatings with no or minimal coating imperfections with a deposition rate comparable to that of conventional dcMS.

### SUMMARY OF THE INVENTION

A modified HIPIMS PVD process and apparatus is disclosed in which charged ion species generated from the same material as the target are less strongly confined by the magnetic field within the region of the target whereby such ion species may more readily escape the magnetic confinement to be deposited on the substrate surface. Accordingly, the present HIPIMS process provides enhanced target-originating ion deposition rates.

According to first aspect of the present invention that is provided a high power impulse magnetron sputtering physical vapour deposition process comprising: generating a plasma using a pulsed magnetron discharge; and generating charged ion species from a target; said process characterised in that: the magnetic field strength of a tangential component of the magnetic field applied in the region of said target is less than 40 mT.

Within the present specification, the term ‘tangential component’ of the magnetic field is defined with respect to the target surface. For example, the tangential component in the case of a planar target is orientated substantially parallel to the target surface and in the case of a target with a circular cross section, the component is tangential to the circle.

The present apparatus and process is suitable for use with a variety of target materials and accordingly the generation of variety of different types of charged ion species from material originating from such cathodic targets. By way of example, the target and corresponding charged ion species may include metals, substantially pure metals, alloys and in particular Al, Si, rare earth elements or elements selected from groups 4, 5 or 6. Additionally, the target materials may include carbon, semiconductor materials and ceramics such as SiC.

The ion species from the target may be generated by sputtering off neutral atoms from the target which are subsequently ionised as they transverse the cathode sheath or the bulk plasma.

The increased deposition rates are achieved by applying a magnetic field of relative weaker field strength in the region of the target which serves to weaken the confinement of plasma electrons and, through ambipolar interaction charged ion species, allowing plasma to escape towards the substrate. In conventional HIPIMS processes a large proportion of the sputtered atoms are ionised by the plasma and confined near the target by the magnetic field trap. The effect of electron and ion confinement in the region of the target is low material deposition rates due to the poor ion transport from target to substrate.

The present process may comprise an initial substrate pretreatment phase in which the substrate surface is etched by the plasma followed by the material deposition phase where the ion species originating from the same material as the target are deposited on the substrate surface. Preferably, the magnetic field strength of the deposition phase is less than that of the pretreatment phase.

So as to achieve a weakened metal ion confinement the present process comprises a magnetic field strength on the target surface of <40 mT and preferably 5-40 mT. The discharge may comprise a pulse duration of greater than 100 μs or 200 μs and preferably a pulse duration of 200 μs to 1 s. The discharge may comprise a discharge current density in the range 0.03 A·cm⁻² to 3 A·cm⁻² and discharge voltage of 900 V and preferably a discharge voltage of 300 V to 2000 V

The deposition rate for the present HIPIMS process is increased by 90% over the deposition rates achievable by conventional HIPIMS sputtering under identical average power, gas pressure and substrate location conditions. Metal ion deposition rates of the present process with Niobium are greater than 0.3 μm·h⁻¹·kW⁻¹ and may be of the order of 0.9 μm·h⁻¹·kW⁻¹ or higher depending upon the system parameters employed.

Preferably, the process comprises a pretreatment stage involving generating plasma using a magnetic field strength in the range 5-60 mT and preferably 40-60 mT to achieve highly ionised plasma where the discharge current density is in the range 0.1 to 5 A·cm⁻². Preferably the pretreatment stage comprises a discharge impulse duration of less than 200 μs. The metal ion deposition rate at the substrate surface during pretreatment may be in the range 0.05 to 0.2 μm·h⁻¹·kW⁻¹ depending upon the coating system parameters.

The process comprises generating a plasma density in the region of the target of the order of 10¹³ cm⁻³. The discharge may be distributed homogeneously over at least 10% of the target surface. Further operative conditions include a discharge voltage in the range −200 to −2000 V, and a gas pressure of 4×10⁻⁴ to 10×10⁻¹ mbar. The present system is compatible for use with a substrate bias voltage optionally during the pre-treatment and/or deposition phases. The substrate bias voltage, during the deposition phase may be 0 to −1000V. During pre-treatment, the substrate bias voltage may be in the range −200 to −2000 V.

According to a second aspect of the present invention there is provided physical vapour deposition apparatus comprising: means to generate a pulsed magnetron discharge; a target from which a plasma of charged ion species may be generated in response to said pulsed magnetron discharge; and an array of magnets capable of producing a magnetic field at said target; said apparatus characterised in that: the magnetic field strength of a tangential component of said magnetic field at said target is less than 40 mT.

The present HIPIMS process may utilise permanent magnets, electomagnets and/or eletromagnetic coils. The degree of ion confinement, in particular those ions originating from the material of the target in the region of the target, may be varied by selecting the strength of the magnetic field and/or by shaping the magnetic field lines to allow plasma to stream in the direction of the substrate(s). The magnetic field may be pulsed synchronously with the impulses of the magnetron discharge. Preferably, the process may further comprise alternating the field strength of the pulsed magnetic field between a relative high and low field strength according to a modulated field strength sequence to provide varying degrees of confinement of the charged ion species as the impulse progresses. Alternatively, a substantially uniform magnetic field may be applied interrupted by a pulsed magnetic field of greater magnetic field strength to induce higher ionisation.

Preferably, the apparatus further comprises means to change the magnetic field strength created by the array of magnets at the target wherein the apparatus is capable of creating a plurality of different discharge current densities at the target for a given voltage. The array of magnets may be moveably mounted relative to the target such that distance between the target and the array of magnets may be adjusted. This particular embodiment is advantageous and serves to decrease the time taken for the entire coating process involving initial pretreatment and subsequent metal deposition. The distance between the magnets or electromagnetic coils may be adjusted using known electronic or mechanical devices which may be operated externally to the internal sputtering vacuum chamber.

Preferably, the apparatus further comprises a magnetron or a plurality of magnetrons and an electrode biased to a ground or positive potential that serves as an anode as described in U.S. Pat. No. 6,352,627. In particular, the apparatus may further comprise an anodic electrode within the deposition chamber having a positively biased voltage relative to the chamber walls which are preferably earthed. This particular embodiment is advantageous and serves to direct the plasma flow away from the chamber walls and on to the anode thereby decreasing substantially plasma losses.

Preferably, the apparatus further comprises a pair of facing magnetrons with opposing magnetic fields or an even number of magnetrons with alternating magnetic field polarity. This particular embodiment is advantageous and serves to create a closed loop magnetic field trap enclosing the entire chamber thus limiting the losses of deposition ions to the chamber walls and improving the deposition rate on the substrates. The field strength may be adjusted by additional magnets or electromagnets using known electronic or mechanical devices to regulate the trapping efficiency.

Optionally, the present apparatus may comprise a pair of magnetrons operated out of phase according to a bipolar pulsed technique (dual magnetron sputtering) as disclosed in Surface and Coatings Technology 98 (1998) 828-833. Accordingly, in alternate pulses the first magnetron serves as a cathode and the second as an anode of the discharge and in the next pulse the first magnetron serves as an anode and the second as a cathode. This could be advantageous for example in the deposition of oxide films to limit the build-up of charge that can lead to arcing.

Where the apparatus further comprises means to change the magnetic field strength created by the array of magnets at the target the apparatus may further comprise an additional duct parallel to the target-substrate path with magnetic field normal to the target. The magnetic field may be generated by permanent magnets or electromagnets. This particular embodiment is advantageous and serves to further improve deposition rates by promoting the transport of electrons and highly ionised plasma originating from the target material from the target to the substrate. In this embodiment, the deposition rate can be increased for single or a plurality of cathodes without the need for an even number of magnetrons or cathodes in a closed field magnetic system. The field strength in the duct may be adjusted using known electronic or mechanical devices to regulate the transport efficiency.

### BRIEF DESCRIPTION OF THE DRAWINGS

For a better understanding of the invention and to show how the same may be carried into effect, there will now be described by way of example only, specific embodiments, methods and processes according to the present invention with reference to the accompanying drawings in which:

FIG. 1 is a schematic, cross sectional plan view of the present deposition apparatus;

FIG. 2 is a cross sectional side elevation view of the cathode target and magnetic array together with magnetic field lines according to known HIPIMS operational parameters;

FIG. 3 is a cross sectional side elevation view of the cathode target and magnetic array together with magnetic field lines according to the present HIPIMS process;

FIG. 4 is a graph of the tangential magnetic field strengths for a conventional HIPIMS process and the present HIPIMS process having a reduced magnetic field strength at the cathode target.

### DETAILED DESCRIPTION

There will now be described by way of example a specific mode contemplated by the inventors. In the following description numerous specific details are set forth in order to provide a thorough understanding. It will be apparent however, to one skilled in the art, that the present invention may be practiced without limitation to these specific details. In other instances, well known methods and structures have not been described in detail so as not to unnecessarily obscure the description.

An investigation was undertaken to determine the influence of magnetic field strength in the proximity of the target on the deposition rate of metal ions deposited via a HIPIMS process.

Although magnetron systems are designed to influence only the electrons, metal ions are also confined indirectly via an ambipolar interaction with electrons. This interaction forces both species to exist in equilibrium in order to sustain quasineutrality which is a fundamental property of the plasma. The degree of confinement of the ion species has been found to increase with increasing the magnetic field strength for a given discharge current and corresponding plasma density and discharge voltage.

In the case of HIPIMS, a large proportion of the sputtered neutrals are ionised by the plasma and confined near the target by the magnetic field trap. The transport of ions to the substrate is strongly diminished and deposition rates drop by a factor of 4-10 depending on the system. The present solution to this problem is to weaken the confinement and allow plasma to escape towards the substrate whilst enabling sufficient metal ionisation.

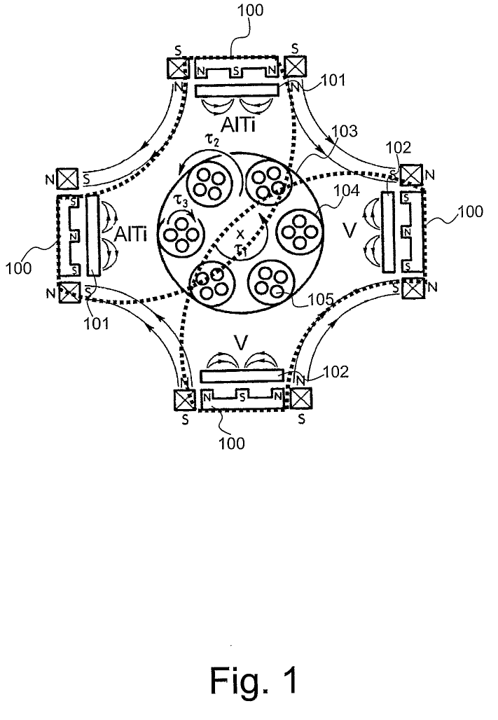

The present investigation was carried out using a four cathode Hauzer HTC 1000-4 PVD coating system. FIG. 1 is a schematic cross section of the coating system. The system comprises four magnetic arrangements positioned at each target (cathode) 101, 102. A three-fold rotateable planetary substrate holder 103 is positioned centrally between the four targets within an approximate 1 m³ system chamber volume. The substrate holder comprises a first rotational axis τ₁ (primary rotation), a secondary axis of rotation τ₂ and a third axis of rotation τ₃.

The present deposition rate investigations were all carried out in a common Ar atmosphere at a working pressure of approximately 2.1×10⁻³ mbar.

The cathodes employed were planar Nb targets of 600×200 mm rectangular dimensions. All HIPIMS discharges were operated in unbalanced magnetron mode via the magnetic arrangements positioned around each cathode. Silicon substrates were used onto which the coatings were deposited.

Four separate deposition cycles were performed to investigate the influence of the magnetic field strength on the deposition rates. In the present investigations, the magnetic field strength at the cathodes was changed by adjusting the distance between each respective magnetic array and each target. Table 1 details the operating parameters for each cycle.

TABLE 1
HIPIMS Discharge Operating Parameters and Deposition Rates

| | | | | | | | | Specific |
|---|---|---|---|---|---|---|---|---|
| | | | | | Target - | | | Deposition Rate |
| Cycle | Pₐᵥ, kW | Ud, V | Jₜ, A · cm⁻² | Pₚₑₐₖ kW | Magnet Distance | Bₜ mT | I_{coil}, A | μm · h⁻¹kW⁻¹ |
| C1 | 10 | 695 | 0.67 | 556 | Near | 50 | 1 × 4 | 0.10 |
| C2 | 10 | 650 | 0.67 | 520 | Near | 50 | 0 | 0.15 |
| C3 | 9.5 | 900 | 0.28 | 306 | Far | 20 | 1 × 4 | 0.95 |
| C4 | 8 | 406 | 0.02 | 8 | Far | 20 | 0 | 1.23 |

where C1=conventional HIPIMS with unbalancing coils; C2=conventional HIPIMS without unbalancing coils; C3=target-magnet distance modified HIPIMS with unbalancing coils; C4=conventional dcMS; Ud=discharge voltage; Id=peak current; Pₐᵥ=average power supplied to the target; Jₜ=target current density; Pₚₑₐₖ=peak power applied at the target; duty=duty cycle; target-magnet distance=distance between cathode and magnetic array; Bₜ=tangential magnetic field strength; I_{coil}=current through secondary magnetic coils to produce unbalanced magnetron mode.

Comparing C3 with C1, by positioning each magnetic array a greater distance from each cathode the current density at the target is considerably lower for C3 (0.28 A·cm⁻²) than the corresponding C1 (0.67 A·cm⁻²). The measured deposition rate for C3, from table 1 is 0.95 μm·h⁻¹·kW⁻¹ whilst the deposition rate for C1 involving a much higher magnetic field, is 0.10 μm·h⁻¹·kW⁻¹. Accordingly, by decreasing the magnetic field strength in the region of the cathode, the plasma confinement near the target decreases which increases the deposition rate as illustrated in table 1.

Some 10% of the deposition rate increase in C3 may be due to an increased sputter yield brought about by the increased discharge voltage of 900 V.

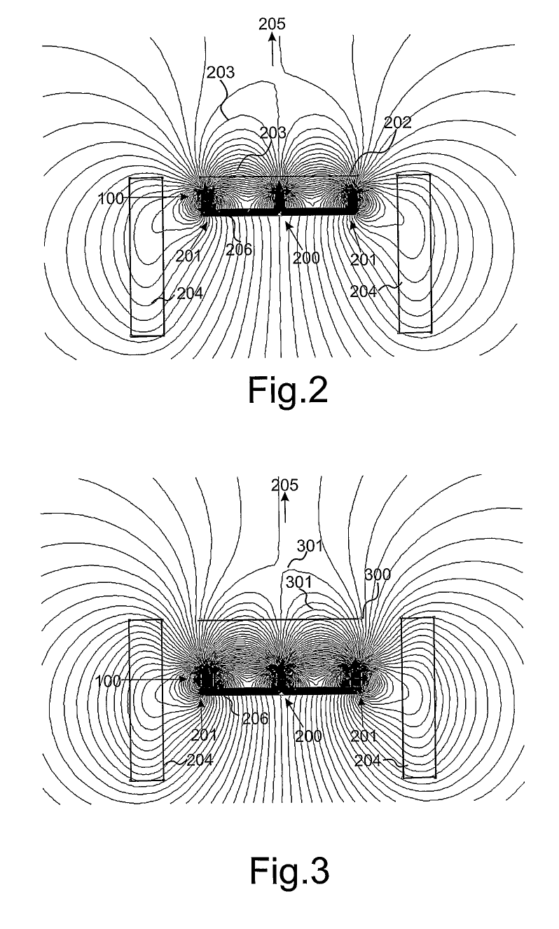

FIGS. 2 and 3 illustrate the differences in the experimental set up of C1 and C3, respectively. FIGS. 2 and 3 illustrate a cross section through the magnetic array and target. Each magnetic array 100 comprises a rectangular arrangement of north polarity magnets 201 including a centrally positioned strip of south polarity magnets 200. A suitable shield 206 is positioned at an opposite face of magnetic array 100 to impede the magnetic field in the direction opposed to the target. A secondary coil 204 is provided concentrically around the permanent magnet array so as to enable the unbalanced magnetron sputtering mode.

In C3, target 202 is positioned much closer to magnetic array 100 (FIG. 2) than C1 where FIG. 3 illustrates the relative positioning of target 300 relative to magnetic array 100. Target 202, 300 is aligned between the magnetic array 100 and the substrate positionally indicated by arrow 205. With the target 202 positioned close to the magnetic array, in C1 (FIG. 2) the density of field lines above the target and the strength of the tangential component of the magnetic field indicated by field lines 203, and hence the plasma confinement, is much greater than that of C3 (FIG. 3) indicated by field lines 301. Accordingly, for the conventional magnetic array alignment of FIG. 2 the magnitude of metal ion confinement, in the region of the target is much greater than the modified target-magnetic array arrangement of FIG. 3.

TABLE 2
Tangential Magnetic Field (Bₜ) Strength Across Target

| | target - mag | target - mag | target - mag |
|---|---|---|---|
| Distance across | distance 55 mm | distance 35 mm | distance 20 mm |
| target cm | (C3¹) Bₜ, mT | (C3²) Bₜ mT | (C1) Bₜ, mT |
| 4 | 19.4 | 30 | 46 |
| 15 | −17.9 | −29 | −47 |

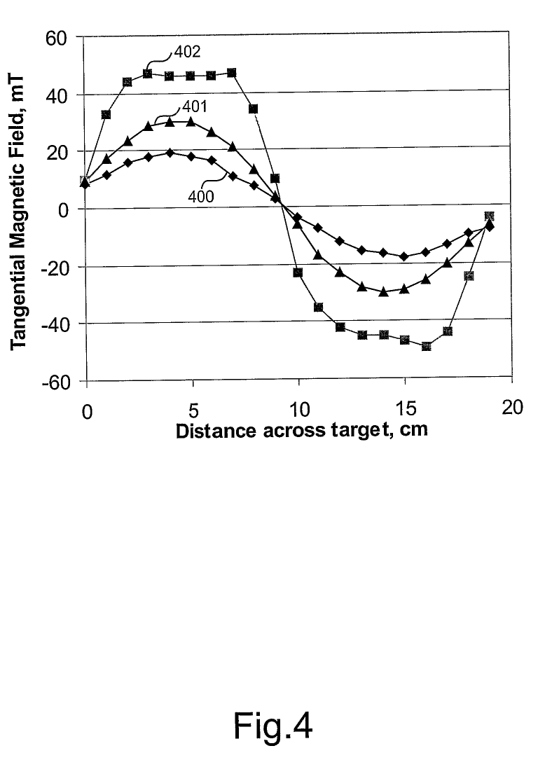

The tangential magnetic field strength and relative distance between the target and magnetic field array are illustrated in table 2 and FIG. 4 for C1 and two variations of C3 where C3¹ represents a target to a magnetic array distance of 55 mm and C3² corresponds to a target to magnetic array distance of 35 mm. Table 2 and FIG. 4 illustrate the tangential magnetic field strength component which is proportional to the extent of charged metal ion trapping. The tangential component of the magnetic field is directional relative to the target and represents a percentage of the total magnetic field strength in the target region.

Referring to FIG. 4, Bₜ for C1 is represented by 402, C3¹ is represented by 401 and C3² is represented by 400 across the distance of the target surface. The deposition rate illustrated in table 1 for C3 corresponds to C3¹ that is a target to magnetic array distance of 55 mm. By comparing Bₜ and the deposition rate of C1 and C3¹ the present investigation reveals that by reducing the tangential component of the magnetic field strength by approximately 64% it is possible to increase the deposition rate, under the HIPIMS discharge of the present investigation, by a factor of 9. This significant reduction in the time required to generate a coating of predetermined thickness is significantly beneficial for industrial coating processes where the coating is either applied in isolation or in-line within a larger manufacturing operation.

The present HIPIMS deposition rate investigation was extended to include the recently reported coating deposition sequence involving substrate pretreatment/etching and subsequent coating deposition (Surface and Coatings Technology 163-164 (2003) 267-272). During pretreatment, charged metal ion species are firstly bombarded onto the substrate surface with high energy involving substrate etching and a degree of metal ion implantation at the substrate surface to guarantee adhesion of the applied coating and tailored interface formation. In the subsequent coating deposition phase the general objective is to produce a dense coating devoid of imperfections such as poor adhesion, localised internal droplet formation and excessive porosity.

Using the present system and HIPIMS discharge parameters, the discharge current density for optimum deposition rates, during the pretreatment stage was found to be in the range 0.1-5 A·cm⁻². That is, the target to magnetic array distance is closer during the pretreatment phase to generate highly ionised plasma to provide intensive sputter-cleaning of the substrate surface. The magnetic field strength is then decreased for the deposition phase sufficient to achieve substantial ionisation of the generated neutral metal species whilst not over confining the charged metal ion species within the plasma generated at the cathode region. For the subsequent coating process following pretreatment, the optimum deposition rate was achieved with a tangential magnetic field strength of 20 mT and discharge current density in the range 0.03-3.0 A·cm⁻². In comparison dcMS typically utilizes a discharge current density of 0.005 to 0.03 A·cm⁻¹.

Because the high power impulses are short (impulses of microsecond duration), the discharge does not transition to an arc phase but is maintained throughout the duration of the pulse as a glow, which is homogeneously distributed over at least 10% of the target area depending on the shape of the confining magnetic field.

This approach differs from existing processes described by Konstantinidis et al where ultra short pulses of 2, 5, 10 or 20 μs duration are utilised. The HIPIMS discharge develops in two stages—the first is an Ar-dominated stage having a duration of a few microseconds where metal neutrals are produced that are not influenced by the magnetic trapping. As more metal becomes available it is ionised and the discharge transitions to the second stage where the plasma is highly ionised and dominated by metal ions which are trapped near the target. The effect of shortening the impulse duration is that the discharge operates in the first stage and is switched off before it enters the second stage.

In the present investigation, and to optimise deposition rates, for the initial pretreatment/etching phase the discharge impulse duration was of the order of less than 200 μs. For the subsequent deposition phase, the discharge pulse duration was much longer being greater than 200 μs and preferably in the range 200 μs to 1 s. However, shorter impulse durations may be employed depending upon the coating system and operational parameters and may be anywhere between 2.0 μs to 1 s.

The present system, due to the reduction in the trapping effect of the plasma may take advantage of shorter impulse intervals (the time between discharge impulse). This allows a weak plasma to be present between impulses and importantly at the start of each new pulse. This in turn allows ignition and high current to be achieved at moderate discharge voltages without the need to preionise the gas.

By utilising a lower plasma confinement and associated lower current density to achieve the higher deposition rates the discharge impulse duration may be increased without risk of arcing and overheating which is otherwise associated with conventional HIPIMS processes utilising conventional current densities and corresponding cathodic magnetic field strengths.

1. A high power impulse magnetron sputtering physical vapour deposition process comprising:
generating a plasma using a pulsed magnetron discharge;
generating charged ion species from a target;
generating a magnetic field at said target; and
said process characterised in that:
said magnetic field is variable between a first magnetic field strength and a second magnetic field strength and wherein said first magnetic field strength of a tangential component of the magnetic field applied in the region of said target is less than 40 mT.

2. The process as claimed in claim 1 wherein said magnetic field strength is created by an array of magnets.

3. The process as claimed in claim 2 wherein a distance between said target and said array of magnets is adjustable.

4. The process as claimed in claim 3 wherein said array of magnets is moveably mounted relative to said target.

5. The process as claimed in claim 3 wherein a discharge current density of said target is variable.

6. A high power impulse magnetron sputtering physical vapour deposition process comprising:
generating a plasma using a pulsed magnetron discharge;
generating charged ion species from a target;
generating a magnetic field at the target; and
said process characterised in that:
said magnetic field strength is variable.

7. The process as claimed in claim 6 wherein said magnetic field strength of a tangential component of said magnetic field applied in a region of said target is less than 40 mT.

8. A high power impulse magnetron sputtering physical vapour deposition process comprising:
generating a plasma using a pulsed magnetron discharge; and
generating charged ion species from a target;
said process characterised in that
a magnetic field strength of a tangential component of a magnetic field applied in a region of said target is less than 40 mT and a discharge current density is in the range of 0.03 A·cm⁻² to 3 A·cm⁻² during deposition of said ion species at a surface of a substrata.

9. The process of claim 8 wherein the process is a coating deposition process.

10. The process as claimed in claim 9 wherein a discharge current density is in the range 0.03 to 3 A·cm⁻² during deposition of said ion species at a surface of a substrate.

11. The process as claimed in claim 10 wherein said discharge comprises an impulse duration of greater than 200 μs.

12. The process as claimed in claim 11 wherein said impulse duration is in the range 200 μs to 1 s.

13. The process as claimed in claim 8 wherein said substrata is biased to a voltage of 0 to −1000V.

14. The process as claimed in claim 13 further comprising:
pretreating said surface of said substrate by generating said plasma using a discharge current density in the range 0.1 to 5 A·cm⁻².

15. The process as claimed in claim 14 wherein said discharge comprises an impulse duration of less than 200 μs during said pretreating of the substrate surface.

16. The process as claimed in claim 14 wherein said substrate is biased to a voltage of −200 to −2000 V.

17. The process as claimed in claim 14 further comprising:
generating a plasma density in the region of said target of the order of 10¹³ cm⁻³.

18. The process as claimed in claim 7 wherein said discharge is distributed homogeneously over at least 10% of a surface of said target.

19. The process as claimed in claim 18 comprising a discharge voltage in the range −200 to −2000 V.

20. The process as claimed in claim 8 comprising an operational gas pressure in the range 4×10⁻⁴ to 10×10⁻¹ mbar.

21. The process as claimed in claim 8 further comprising biasing an additional anodic electrode with a positive voltage relative to the chamber walls.

22. The process as claimed in claim 8 further comprising:
operating at least two magnetrons according to an out of phase bipolar pulsed process in which each magnetron is alternately operated as the anode and cathode according to the bipolar pulsed process.

23. The process as claimed in claim 8 wherein the magnetic field is created using permanent magnets.

24. The process as claimed in claim 8 wherein the magnetic field is created using electromagnets and/or electromagnetic coils.

25. The process as claimed in claim 16 further comprising pulsing said magnetic field synchronously with the impulses of said pulsed magnetron discharge.

26. The process as claimed in claim 23 further comprising alternating the field strength of the pulsed magnetic field between a relative high and low field strength according to a modulated field strength sequence.

27. The process as claimed in claim 23 further comprising:
applying a substantially uniform magnetic field; and
interrupting said substantially uniform magnetic field with a pulsed magnetic field of greater magnetic field strength than said uniform magnetic field.

28. The process as claimed in claim 8 comprising:
a substrate pretreatment stage in which a surface of a substrate is etched by said plasma; and
a deposition stage wherein said ion species are deposited on said surface of said substrate;
wherein a magnetic field strength of said deposition stage is less than that of said pretreatment stage.

29. The process as claimed in claim 8 further comprising:
creating a closed loop magnetic field trap to enclose the chamber confining said plasma, said closed magnetic field trap being configured to inhibit loss of said charged ion species to the walls of said chamber.

30. The process as claimed in claim 8 wherein said charged ion species comprise anyone or a combination of the following set of:
a metal;
a substantially pure metal;
a metal alloy;
a semiconductor material;
a ceramic material;
C, Al, Si; and
a carbon based material.

31. The process as claimed in claim 30 wherein said charged ion species comprises a rare earth element or an element selected from group 4, 5, or 6.

32. A method of coating a substrate using the process according to claim 8.

33. Physical vapour deposition apparatus comprising:
means to generate a pulsed magnetron discharge;
a target from which a plasma of charged ion species may be generated in response to said pulsed magnetron discharge; and
an array of magnets capable of providing a magnetic field at said target;
said apparatus characterised in that
magnetic field strength and a second magnetic field strength and wherein said first magnetic field strength of a tangential component of said magnetic field at said target is less than 40 mT.

34. The apparatus as claimed in claim 33 wherein the apparatus comprises adjustment means to adjust a distance between said target and said array of magnets.

35. The apparatus as claimed in claim 33 wherein said array of magnets is moveably mounted relative to said target.

36. The apparatus as claimed in claim 33 wherein a discharge current density of said target is variable.

37. Physical vapour deposition apparatus comprising:
means to generate a pulsed magnetron discharge:
a target from which a plasma of charged ion species may be generated in response to said pulsed magnetron discharge;
an array of magnets capable of providing a magnetic field at said target; and
said apparatus characterised in that
the apparatus comprises means to vary the magnetic field strength.

38. The apparatus as claimed in claim 37 wherein the magnetic field strength of a tangential component of said magnetic field at said target is less than 40 mT.

39. Physical vapour deposition apparatus comprising:
means to generate a pulsed magnetron discharge;
a target from which a plasma of charged ion species is generated in response to said pulsed magnetron discharge;
an array of magnets capable of providing a magnetic field at said target; and
said apparatus characterised in that:
said magnetic field strength of a tangential component of said magnetic field at said target is less than 40 mT and a discharge current density is in the range of 0.03 A·cm⁻² to 3 A·cm⁻² during deposition of said ion species at a surface of a substrate.

40. The apparatus as claimed in claim 39 in which the apparatus comprises coating deposition apparatus.

41. The apparatus as claimed in claim 33 wherein said array of magnets is moveably mounted relative to said metal target.

42. The apparatus as claimed in claim 33 further comprising:
an additional anodic electrode having a biased positive voltage relative to the chamber walls of said physical vapour deposition apparatus.

43. The apparatus as claimed in claim 33 comprising a pair of magnetrons operated according to a bipolar pulsed technique in which each magnetron is alternately operated as the anode and cathode.

44. The apparatus as claimed in claim 33 wherein said array of magnets comprises permanent magnets.

45. The apparatus as claimed in claim 33 wherein said array of magnets comprises electromagnets and/or electromagnetic coils.

46. The apparatus as claimed in claim 33 wherein a distance between said target and said array of magnets may be adjusted.

47. The apparatus as claimed in claim 33 further comprising:
means to change the magnetic field strength created by said array of magnets at said target;
wherein said apparatus is capable of creating a plurality of different discharge current densities at said target.

48. The apparatus as claimed in claim 33 further comprising:
means to generate a closed loop magnetic field trap about a chamber confining said plasma;
wherein said closed loop magnetic field trap is configured to inhibit loss of said charged ion species to the walls of said chamber.

49. The apparatus as claimed in claim 48 wherein said means to create said dosed loop magnetic field trap comprises:
opposed facing magnetrons with opposing magnetic fields.

50. The apparatus as claimed in claim 48 wherein said means to create said closed loop magnetic field trap comprises:
one or a plurality of magnetrons with alternating magnetic field polarity.

51. The apparatus as claimed in claim 50 further comprising a duct positioned substantially parallel to a direct path between said target and a substrata;
wherein said duct is configured to channel said charged ion species from said target to said substrate.

52. The apparatus as claimed in claim 33 wherein the apparatus is arranged, in use, for a substrate pretreatment stage in which a surface of a substrate is etched by said plasma and the apparatus is subsequently arranged, in use, for a deposition stage wherein said ion species are deposited on said surface of said substrate; and
wherein a magnetic field strength of said deposition stage is less than that of said pretreatment stage.
